(19) United States
(12) Patent Application Publication
(10) Pub. No.: US 2025/0336845 A1
(43) Pub. Date: Oct. 30, 2025

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Chieh-Lung LAI, Taichung City (TW); Hsien-Wei CHEN, Hsinchu City (TW); Shin-Puu JENG, Hsinchu (TW)

(21) Appl. No.: 18/645,747

(22) Filed: Apr. 25, 2024

(51) Int. Cl. H01L 23/00; H01L 21/48; H01L 23/31; H01L 23/538; H01L 25/065; H01L 25/18; H10B 80/00

(52) U.S. Cl. CPC H01L 23/564; H01L 21/4853; H01L 23/5385; H01L 23/3185; H01L 23/3192; H01L 24/16; H01L 24/32; H01L 24/73; H01L 24/81; H01L 24/83; H01L 24/92; H01L 25/0655; H01L 25/18; H01L 2224/16225; H01L 2224/32225; H01L 2224/73204; H01L 2224/81815; H01L 2224/83102; H01L 2224/92125; H01L 2924/1431; H01L 2924/1432; H01L 2924/14361; H10B 80/00

(57) ABSTRACT

A package structure is provided. The package structure includes a circuit substrate and a redistribution layer over the circuit substrate. The package structure includes an interconnect chip disposed between the circuit substrate and the redistribution layer. The package structure includes a plurality of conductive connectors around the interconnect chip. The package structure includes a plurality of dummy bars between the interconnect chip and the conductive connectors. The dummy bars are electrically insulated from the conductive connectors. The package structure also includes an underfill disposed between the circuit substrate and the redistribution layer and encapsulating the interconnect chip, the dummy bars and the conductive connectors.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three-dimensional integrated circuits (3DICs) are a recent development in semiconductor packaging in which multiple semiconductor dies are stacked upon one another, using package-on-package (PoP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, for example. However, there are many challenges related to 3DICs.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 illustrates a top view of a package structure in accordance with some embodiments.

FIGS. 2A through 2H illustrate cross-sectional views of various stages of a method for fabricating the package structure in accordance with some embodiments.

FIG. 3 illustrates a schematic top view of the conductive connectors and the dummy bars in accordance with some embodiments.

FIGS. 4A through 4C illustrate cross-sectional views of intermediate steps of a method for fabricating the package structure in accordance with some embodiments.

FIG. 5 illustrates a cross-sectional view of the package structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and method for fabricating the same are provided. The package structure includes a plurality of dummy bars that are disposed between the circuit substrate and the redistribution layer (RDL), and encapsulated by the underfill. Accordingly, the dummy bars provide capillary force for the underfill, which may be filled between the circuit substrate and the redistribution layer more smoothly, thereby reducing voids or cavities between the circuit substrate and the redistribution layer. Therefore, the yield of the package structure may be increased. In addition, the dummy bars may be formed over the circuit substrate or the redistribution layer by different process, depending on the material of the underfill. As a result, the process cost or yield may be improved.

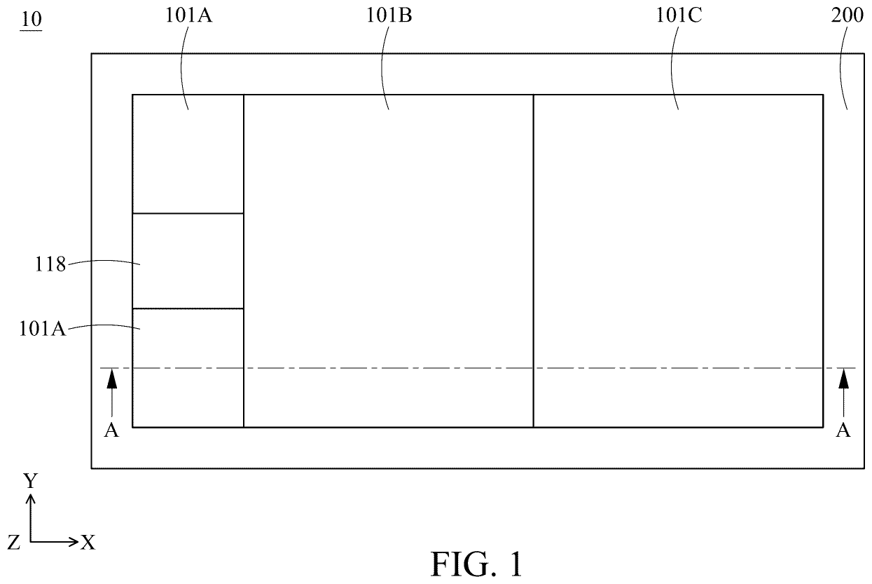

FIG. 1 illustrates a top view of a package structure 10 in accordance with some embodiments. For example, the package structure 10 includes or is a package including a chip-on-wafer-on-substrate (CoWoS) package. However, the present disclosure is not limited thereto. In some embodiments, the package structure 10 includes or is a package including a multi-chip stacked package, a chip on wafer (CoW) package, an integrated fan-out (InFO) package, a three-dimensional integrated circuit (3DIC) package, or a combination thereof. In some embodiments, the package structure 10 includes an InFO package. In some embodiments, the package structure 10 includes a plurality of semiconductor dies 101A, 101B, and 101C, and a molding material 118 for encapsulating the semiconductor dies 101A, 101B, and 101C. For example, the semiconductor dies 101A, 101B, and 101C may include active elements or functional elements and passive elements so as to perform different functions. In some embodiments, the semiconductor dies 101A may be or include a high bandwidth memory (HBM) die, and the semiconductor dies 101B or 101C may each be or include a system-on-chip (SoC) die. However, the present disclosure is not limited thereto. For example, the semiconductor dies 101A, 101B, and 101C may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die or an application processor (AP) die, or may independently be or include a memory die such as a high bandwidth memory (HBM) die. In some embodiments, the package structure 10 includes at least one of AP dies, LSI dies or SoC dies.

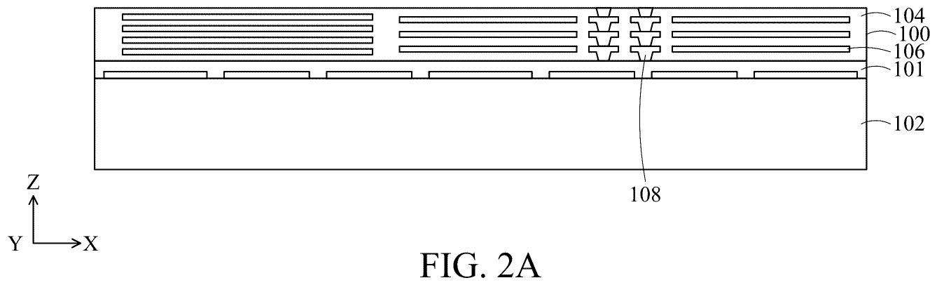

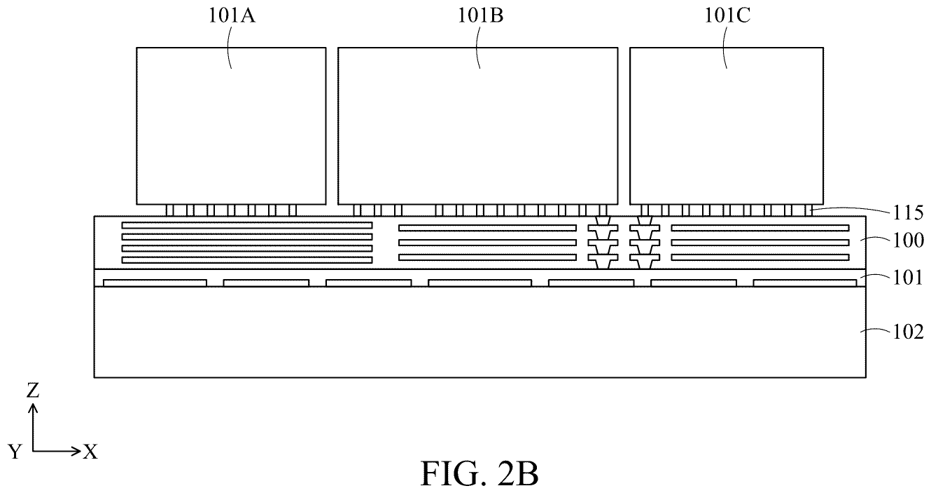

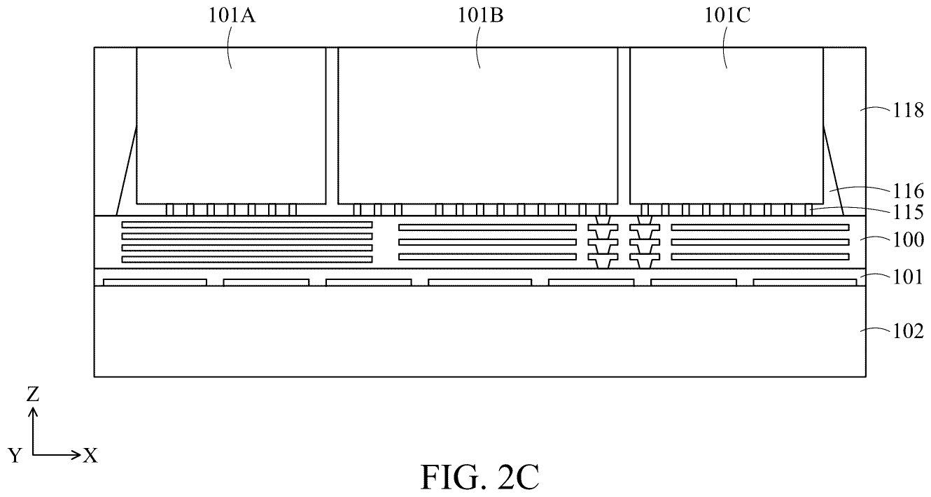

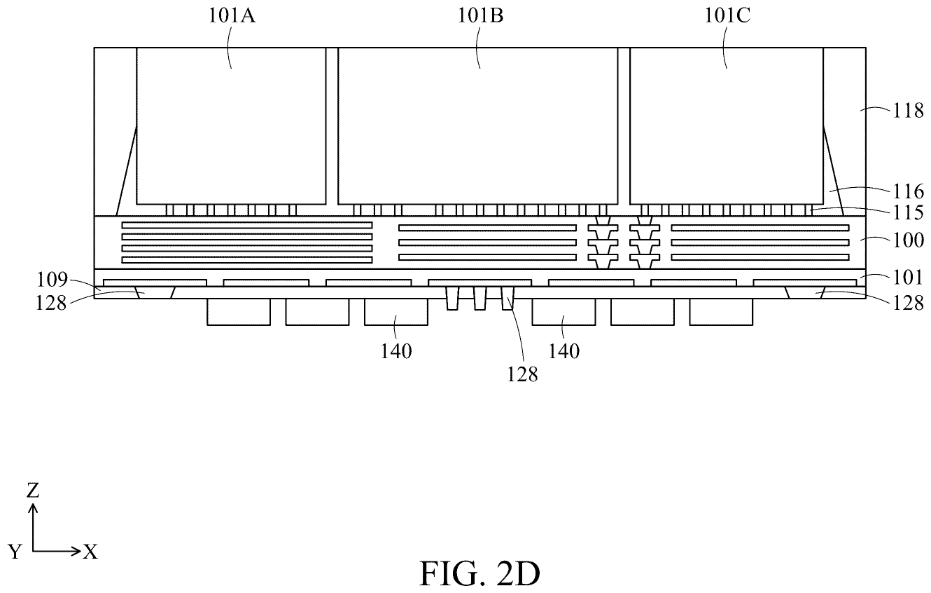

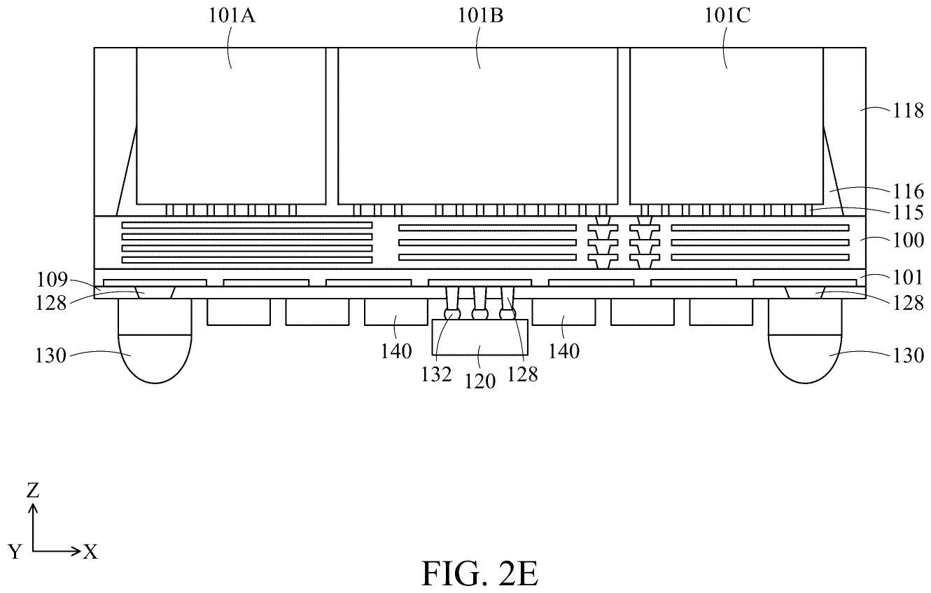

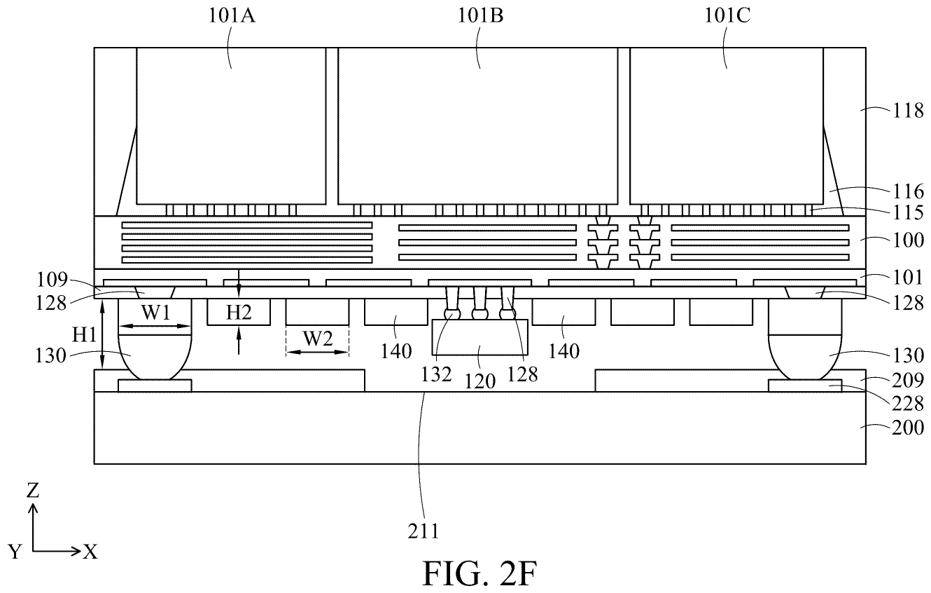

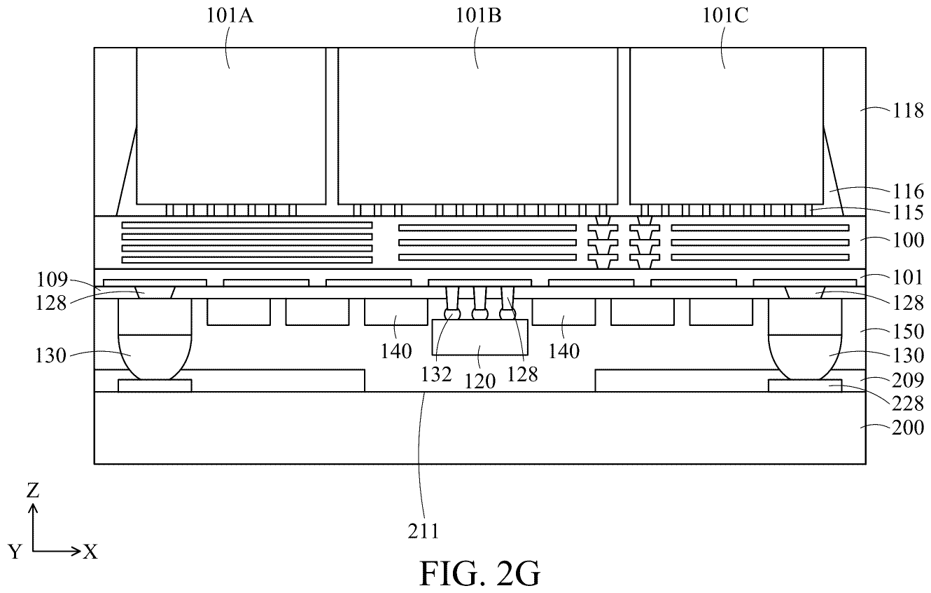

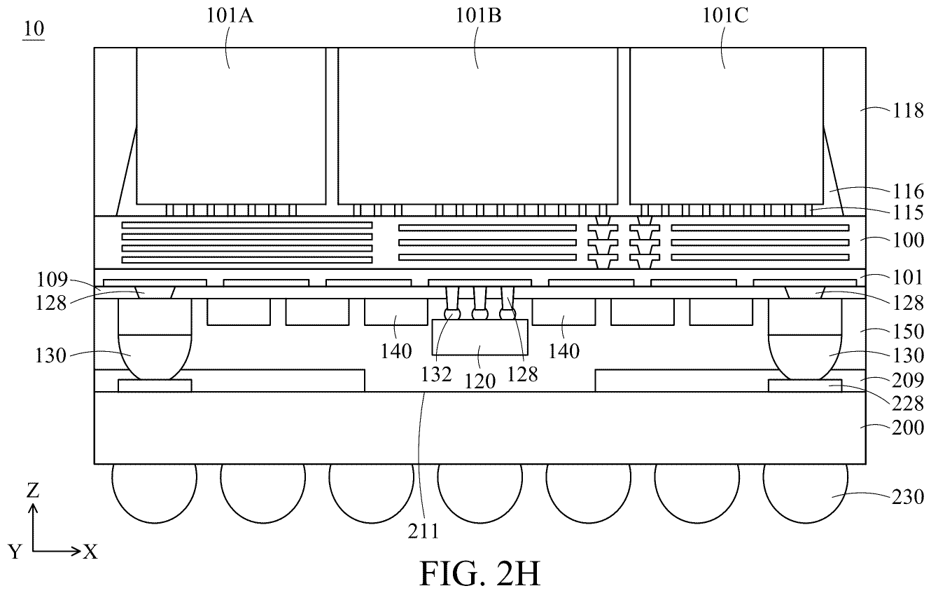

FIGS. 2A through 2H illustrate cross-sectional views of various stages of method for fabricating the package structure 10 in accordance with some embodiments. As shown in FIG. 2A, a carrier substrate 102 is provided. The carrier substrate 102 may be a glass carrier substrate, a ceramic carrier substrate, or the like. In some embodiments, the carrier substrate 102 includes a wafer, such that multiple packages can be formed on the carrier substrate 102 simultaneously. In some embodiments, a release layer (not shown) is disposed on the carrier substrate 102 and formed of a polymer-based material, which may be removed along with the carrier substrate 102 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. In some embodiments, the release layer may be dispensed as a liquid and cured, may be a laminate film laminated onto the carrier substrate 102, or may be the like. In some embodiments, the top surface of the release layer is leveled and has a high degree of planarity.

In addition, a redistribution layer 100 is formed over the carrier substrate 102. In some embodiments, the metallization patterns may also be referred to as redistribution layers or redistribution lines. The redistribution layer 100 is shown as an example having multiple layers of metallization patterns 106 and dielectric layers 104 that are alternatively stacked. In some embodiments, the dielectric layer 104 is formed of a photo-sensitive material such as PBO, polyimide, BCB, or the like, which may be patterned using a lithography mask. In some embodiments, the dielectric layers 104 are formed by spin coating, lamination, CVD, the like, or a combination thereof. In some embodiments, the dielectric layer 104 may be patterned by an acceptable process, such as by exposing and developing the dielectric layers 104 to light when the dielectric layers 104 are a photo-sensitive material or by etching using, for example, an anisotropic etch.

In some embodiments, the metallization patterns 106 include conductive elements extending along the major surface of the dielectric layers 104 and extending through the dielectric layers 104. As an example to form the metallization pattern 106, a seed layer is formed over the dielectric layer 104 and in the openings extending through the dielectric layer 104. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the metallization pattern 106. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the metallization pattern 106. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

In some embodiments, the redistribution layer 100 also includes a dielectric layer 101, which includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the dielectric layer 101 is formed, for example, by spin coating, lamination, chemical vapor deposition (CVD), or the like. In some embodiments, a plurality of via structures 108 are formed in the redistribution layer 100 and electrically coupled to the metallization pattern 106. In some embodiments, the via structures 108 have a tapered profile in the cross-sectional view. For example, the width of the via structures 108 gradually decreases towards the dielectric layer 101. However, the present disclosure is not limited thereto. In some other embodiments, the via structures 108 may have a rectangular profile in the cross-sectional view. In some embodiments, the via structures 108 are formed of tungsten (W), cobalt (Co), nickel (Ni), copper (Cu), silver (Ag), gold (Au), aluminum (Al), any other suitable conductive material, or a combination thereof. However, the present disclosure is not limited thereto.

Then, as shown in FIG. 2B, the semiconductor dies 101A, 101B, and 101C are bonded onto the redistribution layer 100 via a plurality of conductive connectors 115. For example, the conductive connectors 115 may be referred to as micro bumps, but the present disclosure is not limited thereto. In some embodiments, a plurality of bonding features (not shown) are formed on the redistribution layer 100. For example, the bonding features on the redistribution layer 100 include conductive material such as tungsten (W), cobalt (Co), nickel (Ni), copper (Cu), silver (Ag), gold (Au), aluminum (Al), any other suitable conductive material, or a combination thereof. In some embodiments, the bonding features on the redistribution layer 100 are formed corresponding to the semiconductor dies 101A, 101B, and 101C to be bonded. However, the present disclosure is not limited thereto.

Similarly, a plurality of bonding features (not shown) are formed on the semiconductor dies 101A, 101B, and 101C. For example, the bonding features on the semiconductor dies 101A, 101B, and 101C include conductive material such as tungsten (W), cobalt (Co), nickel (Ni), copper (Cu), silver (Ag), gold (Au), aluminum (Al), any other suitable conductive material, or a combination thereof. In some embodiments, the bonding features on the redistribution layer 100 are aligned with the bonding features on the semiconductor dies 101A, 101B, and 101C to form electrical connection between the redistribution layer 100 and the semiconductor dies 101A, 101B, and 101C.

In some embodiments, the conductive connectors 115 are provided in between the bonding features, and a reflow process is performed so that the conductive connectors 115 are electrically connected to the redistribution layer 100 and the semiconductor dies 101A, 101B, and 101C. In some embodiments, the conductive connectors 115 include a conductive material such as solder, tin, or the like. To be more specific, for example, the conductive connectors 115 are formed by initially forming a layer of solder through evaporation, electroplating, printing, solder transfer, ball placement, or the like. Thereafter, the reflow process may be performed in order to shape the solder material, and so that the conductive connectors 115 are joined with the redistribution layer 100 and the semiconductor dies 101A, 101B, and 101C. However, the present disclosure is not limited thereto.

Then, as shown in FIG. 2C, an underfill 116 is formed over the redistribution layer 100 and between the semiconductor dies 101A, 101B, and 101C. In some embodiments, the underfill 116 is located around the conductive connectors 115. In some embodiments, the underfill 116 is formed by a capillary flow process after the semiconductor dies 101A, 101B, and 101C are attached or is formed by a suitable deposition method before the semiconductor dies 101A, 101B, and 101C are attached. In some embodiments, the underfill 116 is also between the semiconductor dies 101A, 101n, and 101C.

In some embodiments, a molding material 118 is supplied over the redistribution layer 100 and covers the semiconductor dies 101A, 101B, and 101C and the underfill 116. After formation, the molding material 118 encapsulates the semiconductor dies 101A, 101B, and 101C and the conductive connectors 115 over the redistribution layer 100. In some embodiments, the molding material 118 may include epoxy molding compound (EMC). For example, the molding material 118 includes polymethyl methacrylate (PMMA), acrylonitrile butadiene styrene (ABS), polyamide (PA), polycarbonate (PC), polyethylene (PE), polyoxymethylene (POM), polypropylene (PP), polystyrene (PS), thermoplastic elastomer (TPE), thermoplastic polyurethane (TPU), etc.), epoxy, or the like. In some embodiments, the molding material 118 is supplied by compression molding, transfer molding, or the like. In some embodiments, the molding material 118 is supplied in liquid or semi-liquid form and then subsequently cured, which increases the mobility of the molding material 118 and therefore being able to fill in the gap (if present) between the semiconductor dies 101A, 101B, and 101C with relatively high aspect ratio. In some embodiments, a planarization process (such as, chemical mechanical polish (CMP), molding compound grinding (MCG) or any other suitable planarization process) may be performed to remove and planarize the upper surface of the molding material 118. As a result, the top surface of the molding material 118, and the top surfaces of the semiconductor dies 101A, 101B, and 101C are substantially coplanar (within process variation).

Then, as shown in FIG. 2D, the carrier substrate 102 is detached (or “de-bonded”) from the redistribution layer 100, e.g., the dielectric layer 101. In accordance with some embodiments, the removal of the carrier substrate 102 includes projecting a light such as a laser light or an UV light on the release layer so that the release layer decomposes under the heat of the light and the carrier substrate 102 can be removed. However, the present disclosure is not limited thereto. In some embodiment, a passivation layer 109 is formed on the redistribution layer 100 (in particular, the dielectric layer 101), and a plurality of conductive features 128 are formed in the passivation layer 109. In some embodiments, a plurality of dummy bars 140 are formed on the passivation layer 109. In some embodiments, the dummy bars 140 are made of insulation material, such as polyimide (PI), polybenzoxazole (PBO), etc. For example, the dummy bars 140 are formed by photolithography process. To be more specific, the insulation material is deposited on the passivation layer 109 and then etched to form the dummy bars 140. However, the present disclosure is not limited thereto. In some embodiments, the conductive features 128 are exposed from the dummy bars 140. As a result, the dummy bars 140 would not be interfered with the electrical connection of the package structure, improving the reliability of the package structure. In some embodiments, during the formation of the passivation layer 109 and the conductive features 128, a carrier substrate (not shown) may be bonded over the molding material 118 and the semiconductor dies 101A, 101n, and 101C for supporting the overall structure.

Next, as shown in FIG. 2E, a plurality of conductive connectors 130 are formed on the conductive features 128. For example, the conductive connectors 130 may include controlled collapse chip connection (C4) bumps, but the present disclosure is not limited thereto. In some embodiments, the conductive connectors 130 may include solder bumps, copper bumps, micro bumps, electroless nickel-electroless palladium-immersion gold technique (ENEPIG) formed bumps, ball grid array (BGA) bumps, copper pillars, or the like. In some embodiments, the dummy bars 140 may be laterally spaced apart from the conductive connectors 130. However, the present disclosure is not limited thereto.

In some embodiments, interconnect chip 120 is bonded to the conductive features 128 via a plurality of conductive connectors 132. For example, the conductive connectors 132 are formed on the conductive features 128. In some embodiments, the conductive connectors 132 may include controlled collapse chip connection (C4) bumps, solder bumps, copper bumps, micro bumps, electroless nickel-electroless palladium-immersion gold technique (ENEPIG) formed bumps, ball grid array (BGA) bumps, copper pillars, or the like. In some embodiments, the conductive connectors 132 may be spaced apart from the dummy bars 140. However, the present disclosure is not limited thereto. In some embodiments, the interconnect chip 120 overlaps at least one of the semiconductor dies 101A, 101B, and 101C in the normal direction (for example, parallel to the Z direction) of the redistribution layer 100. The interconnect chip 120 may be configured to transmit signals between the semiconductor dies 101A, 101B, and 101C, and therefore enhancing the performance of the package structure.

In some embodiments, the conductive connectors 130 and the conductive connectors 132 may be formed prior to the formation of the dummy bars 140. In these embodiments, some of the dummy bars 140 may be in contact with the conductive connectors 130 or the conductive connectors 132. However, the present disclosure is not limited thereto. Since the dummy bars 140 are made from the insulation material, the dummy bars 140 would not interfere the signal transmission via the conductive connectors 130 or the conductive connectors 132.

Then, as shown in FIG. 2F, a circuit substrate 200 is bonded to the redistribution layer 100. In some embodiments, a passivation layer 209 is formed over the circuit substrate 200, and a plurality of conductive features 228 are formed in the passivation layer 209. In some embodiments, an opening 211 is formed in the passivation layer 209 and corresponding to the interconnect chip 120. For example, the opening 211 in the passivation layer 209 is located directly below the interconnect chip 120. In some embodiments, the width of the opening 211 is greater than the width of the interconnect chip 120 in a horizontal direction (for example, parallel to the X direction). However, the present disclosure is not limited thereto. The formation of the opening 211 may provide sufficient space for the interconnect chip 120 and therefore help to achieve the miniaturization of the overall height of the package structure. In some embodiments, the dummy bars 140 partially overlap the opening 211 in the normal direction (for example, parallel to the Z direction) of the circuit substrate 200. However, the present disclosure is not limited thereto. In some other embodiments, the dummy bars 140 may be spaced apart from the opening 211.

In some embodiments, the height H1 of the conductive connectors 130 may be in a range from about 20 μm to about 200 μm, and the width W1 of the conductive connectors 130 may be in a range from about 50 μm to about 200 μm. That is to say, the height H1 of the conductive connectors 130 may be greater than or equal to about 20 μm and less than or equal to about 200 μm. The width W1 of the conductive connectors 130 may be greater than or equal to about 50 μm and less than or equal to about 200 μm. However, the present disclosure is not limited thereto. In some embodiments, the height H2 of the dummy bars 140 may be less than the height H1 of the conductive connectors 130, and the width W2 of the conductive connectors 130 may be less than the width W1 of the conductive connectors 130. That is, the dummy bars 140 are spaced apart from the passivation layer 209 on the circuit substrate 200. For example, the ratio of the height H2 of the dummy bars 140 to the height H1 of the conductive connectors 130 may be in a range from about 0.1 to about 0.9. The ratio of the width W2 of the dummy bars 140 to the width W1 of the conductive connectors 130 may be in a range from about 0.1 to about 0.9. However, the present disclosure is not limited thereto.

Next, as shown in FIG. 2G, an underfill 150 is disposed between the circuit substrate 200 and the redistribution layer 100, and encapsulates the interconnect chip 120, the dummy bars 140 and the conductive connectors 130. In some embodiments, the underfill 150 is formed by a capillary flow process after the circuit substrate 200 is bonded to the redistribution layer 100. With the arrangement of the dummy bars 140, the capillary force may be provided for the underfill 150, which may be filled between the circuit substrate 200 and the redistribution layer 100 more smoothly, thereby reducing voids or cavities between the circuit substrate 200 and the redistribution layer 100. As a result, the yield of the package structure may be increased.

FIG. 2H, a plurality of conductive connectors 230 are formed on the circuit substrate 200. For example, the conductive connectors 230 may include ball grid array (BGA) bumps, but the present disclosure is not limited thereto. In some embodiments, the conductive connectors 230 may include controlled collapse chip connection (C4) bumps, solder bumps, copper bumps, micro bumps, electroless nickel-electroless palladium-immersion gold technique (ENEPIG) formed bumps, copper pillars, or the like. However, the present disclosure is not limited thereto. As a result, an exemplary package structure 10 is formed.

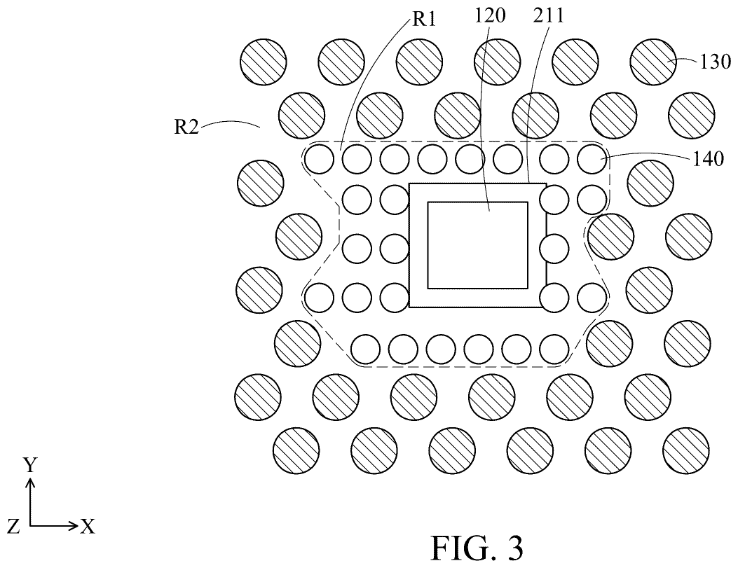

FIG. 3 illustrates a schematic top view of the conductive connectors 130 and the dummy bars 140 in accordance with some embodiments. As shown in FIG. 3, the dummy bars 140 are disposed on each side of the interconnect chip 120, and the conductive connectors 130 surround the dummy bars 140 and the interconnect chip 120. In some embodiments, the conductive connectors 130 are spaced apart from the interconnect chip 120, and a first region R1 may be defined as the region where the dummy bars 140 and the interconnect chip 120 are disposed. A second region R2 may be defined as the region where the conductive connectors 130 are disposed, and the second region R2 may be located outside the first region R1. It should be noted that this embodiment is not intended to limit the shapes and locations of the first region R1 and the second region R2. In some embodiments, the distance between two adjacent dummy bars 140 is less than the distance between two adjacent conductive connectors 130. For example, the distances between the adjacent dummy bars 140 may be measured from the adjacent edges of the dummy bars 140, but the present disclosure is not limited thereto. In some embodiments, the dummy bars 140 are arbitrarily arranged around the interconnect chip 120, and the amount of the dummy bars 140 on the first side (for example, the left side) of the interconnect chip 120 is different from the amount of the dummy bars 140 on the second side (for example, the right side) of the interconnect chip 120. However, the present disclosure is not limited thereto.

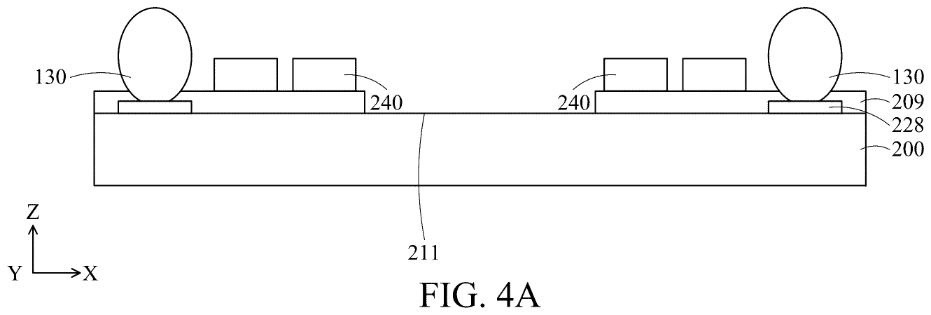

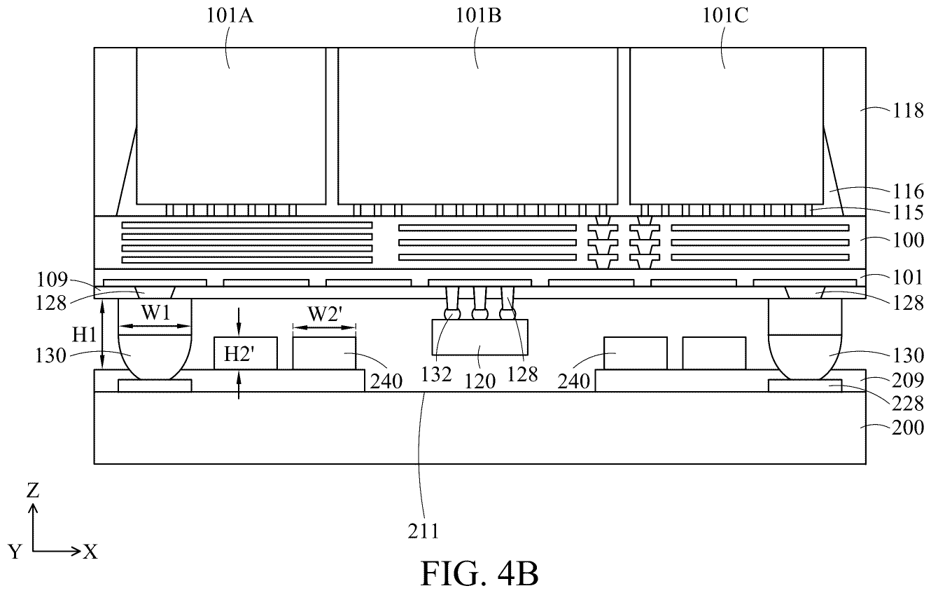

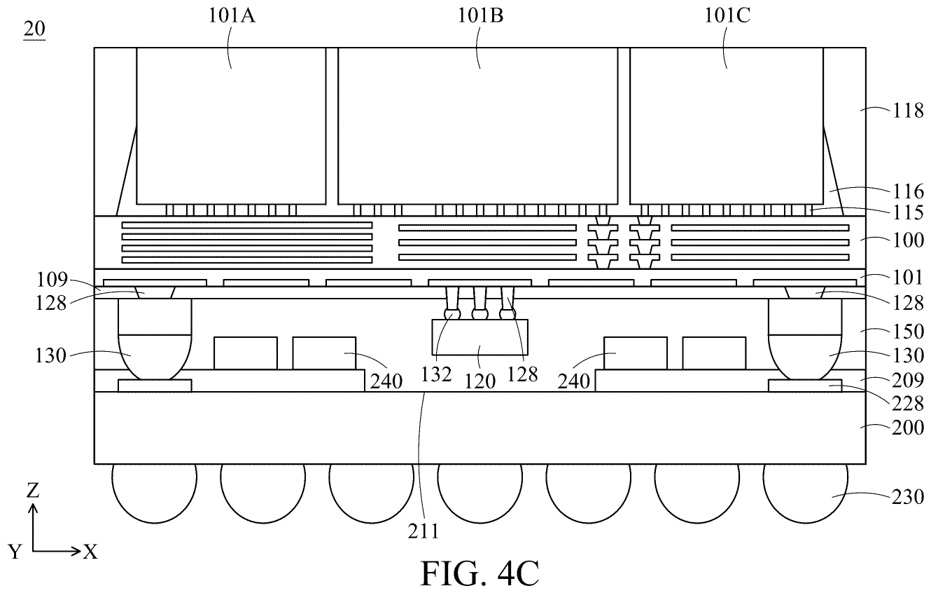

FIGS. 4A through 4C illustrate cross-sectional views of intermediate steps of a method for fabricating the package structure 20 in accordance with some embodiments. It should be noted that the structures and/or elements in the present embodiment are similar to structures and/or elements shown in FIG. 2H, and therefore these structures and/or elements will be labeled with similar numerals and will not be discussed in detail again. As shown in FIG. 4A, a plurality of dummy bars 240 are formed on the passivation layer 209. In some embodiments, an opening 211 is formed in the passivation layer 209, and the dummy bars 240 are laterally spaced apart from the opening 211. In some embodiments, the dummy bars 240 may be formed along with the conductive connectors 130, which are formed on the conductive features 228. For example, the dummy bars 240 are formed by the stencil print process. To be more specific, the material is printed on the passivation layer 209 and form the dummy bars 240, and the dummy bars 240 may be electrically insulated from the conductive connectors 130. In some embodiments, the conductive connectors 130 are spaced apart from the dummy bars 240, and therefore the dummy bars 240 would not interfere the signal transmission via the conductive connectors 130. As a result, the formation of the dummy bars 240 may be simplified, reducing the process time and cost for fabricating the package structure.

Then, as shown in FIG. 4B, the circuit substrate 200 is bonded to the redistribution layer 100. It should be noted that the redistribution layer 100 may be formed by the processes shown in FIGS. 2A through 2E, and therefore will not be discussed in detail below. In some embodiments, after the bonding of the circuit substrate 200 and the redistribution layer 100, the height H1 of the conductive connectors 130 may be in a range from about 20 μm to about 200 μm, and the width W1 of the conductive connectors 130 may be in a range from about 50 μm to about 200 μm. That is to say, the height H1 of the conductive connectors 130 may be greater than or equal to about 20 m and less than or equal to about 200 μm. The width W1 of the conductive connectors 130 may be greater than or equal to about 50 μm and less than or equal to about 200 μm. However, the present disclosure is not limited thereto. In some embodiments, the height H2′ of the dummy bars 240 may be less than the height H1 of the conductive connectors 130, and the width W2′ of the conductive connectors 130 may be less than the width W1 of the conductive connectors 130. That is, the dummy bars 240 are spaced apart from the passivation layer 109 on the redistribution layer 100. For example, the ratio of the height H2′ of the dummy bars 240 to the height H1 of the conductive connectors 130 may be in a range from about 0.1 to about 0.9. The ratio of the width W2′ of the dummy bars 240 to the width W1 of the conductive connectors 130 may be in a range from about 0.1 to about 0.9. However, the present disclosure is not limited thereto.

Next, as shown in FIG. 4C, an underfill 150 is disposed between the circuit substrate 200 and the redistribution layer 100, and encapsulates the interconnect chip 120, the dummy bars 240 and the conductive connectors 130. In some embodiments, the underfill 150 is formed by a capillary flow process after the circuit substrate 200 is bonded to the redistribution layer 100. With the arrangement of the dummy bars 240, the capillary force may be provided for the underfill 150, which may be filled between the circuit substrate 200 and the redistribution layer 100 more smoothly, thereby reducing voids or cavities between the circuit substrate 200 and the redistribution layer 100. As a result, the yield of the package structure 20 may be increased.

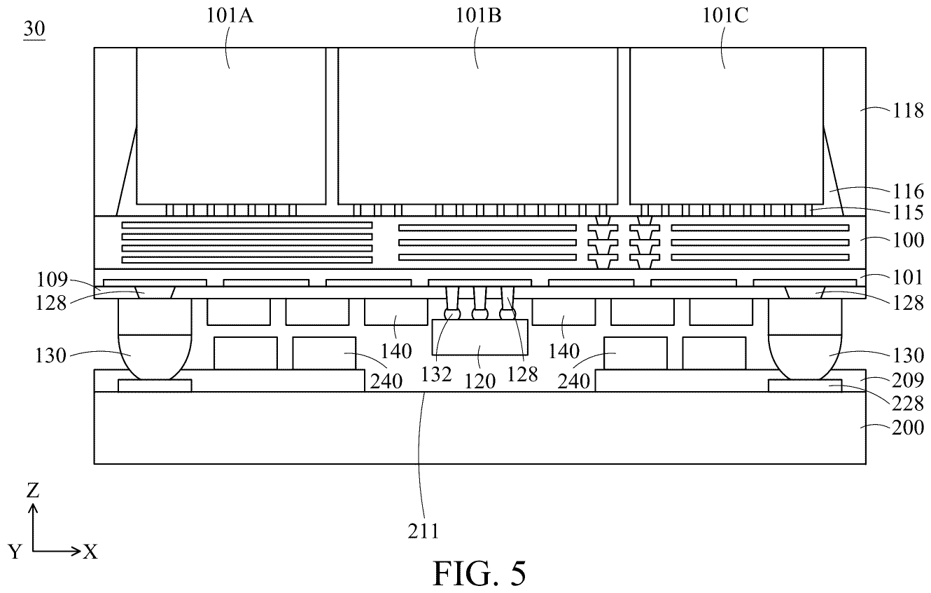

FIG. 5 illustrates a cross-sectional view of the package structure 30 in accordance with some embodiments. It should be noted that the structures and/or elements in the present embodiment are similar to structures and/or elements shown in FIG. 2H, and therefore these structures and/or elements will be labeled with similar numerals and will not be discussed in detail again. As shown in FIG. 5, the dummy bars 140 are disposed on the redistribution layer 100, and the dummy bars 240 are disposed on the circuit substrate 200. In some embodiments, the dummy bars 140 and 240 are misaligned with the interconnect chip 120 in the normal direction of the circuit substrate 200. In some embodiments, the width of the dummy bars 140 is different from the width of the dummy bars 240 since their formation methods are different. In some embodiments, the edge of one of the dummy bars 140 may be misaligned with the edge of one of the dummy bars 140. In some embodiments, the dummy bars 140 are separated from the dummy bars 240. However, the present disclosure is not limited thereto. In some embodiments, the dummy bars 140 may be in contact with the dummy bars 240. It should be noted that the dummy bars 140 and 240 may be selectively formed over the circuit substrate 200 or the redistribution layer 100 depending on the material of the underfill 150. As a result, the process cost or yield of the package structure may be optimized.

Embodiments of package structures and method for fabricating the same are provided. The package structure includes a plurality of dummy bars that are disposed between the circuit substrate and the redistribution layer, and encapsulated by the underfill. Accordingly, the dummy bars provide capillary force for the underfill, which may be filled between the circuit substrate and the redistribution layer more smoothly, thereby reducing voids or cavities between the circuit substrate and the redistribution layer. Therefore, the yield of the package structure may be increased. In addition, the dummy bars may be formed over the circuit substrate or the redistribution layer by different process, depending on the material of the underfill. As a result, the process cost or yield may be optimized. In particular, the dummy bars may be formed over the redistribution layer by photolithography process, so that the dummy bars may be located closer to the interconnect chip, thereby reducing the risk of voids or defects in the underfill. Also, the dummy bars may be formed over the circuit substrate by stencil print process, so that the process for fabricating the dummy bars may be simplified, thereby reducing the time and cost of the overall process.

In some embodiments, a package structure is provided. The package structure includes a circuit substrate and a redistribution layer over the circuit substrate. The package structure includes an interconnect chip disposed between the circuit substrate and the redistribution layer. The package structure includes a plurality of conductive connectors around the interconnect chip. The package structure includes a plurality of dummy bars between the interconnect chip and the conductive connectors. The dummy bars are electrically insulated from the conductive connectors. The package structure also includes an underfill disposed between the circuit substrate and the redistribution layer and encapsulating the interconnect chip, the dummy bars and the conductive connectors.

In some embodiments, a package structure is provided. The package structure includes a circuit substrate and a redistribution layer over the circuit substrate. The redistribution layer includes a first region and a second region outside the first region. The package structure includes an interconnect chip disposed in the first region. The package structure includes a plurality of dummy bars disposed in the first region and around the interconnect chip. The package structure includes a plurality of conductive connectors in the second region. The package structure also includes an underfill disposed between the circuit substrate and the redistribution layer and encapsulating the interconnect chip, the dummy bars and the conductive connectors.

In some embodiments, a method for fabricating a package structure is provided. The method includes bonding a plurality of semiconductor dies over a first surface of the redistribution layer. The method includes bonding an interconnect chip over a second surface of the redistribution layer. The interconnect chip is located directly below the plurality of semiconductor dies. The method includes forming a plurality of conductive connectors around the interconnect chip. The method includes forming a plurality of dummy bars between the interconnect chip and the conductive connectors. The method includes bonding the redistribution layer to a circuit substrate. The method also includes filling an underfill between the redistribution layer and the circuit substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a circuit substrate;
a redistribution layer over the circuit substrate;
an interconnect chip disposed between the circuit substrate and the redistribution layer;
a plurality of conductive connectors around the interconnect chip;
a plurality of dummy bars between the interconnect chip and the conductive connectors, wherein the dummy bars are electrically insulated from the conductive connectors; and
an underfill disposed between the circuit substrate and the redistribution layer and encapsulating the interconnect chip, the dummy bars and the conductive connectors.

2. The package structure as claimed in claim 1, wherein the dummy bars are formed on the redistribution layer and spaced apart from the circuit substrate.

3. The package structure as claimed in claim 2, further comprising a passivation layer over the circuit substrate, wherein an opening is formed in the passivation layer and below the interconnect chip, and the dummy bars partially overlap the opening in a normal direction of the circuit substrate.

4. The package structure as claimed in claim 2, wherein a ratio of a height of the conductive connectors to a height of the dummy bars is from 0.1 to 0.9.

5. The package structure as claimed in claim 2, wherein a ratio of a width of the conductive connectors to a width of the dummy bars is from 0.1 to 0.9.

6. The package structure as claimed in claim 1, further comprising:
a plurality of semiconductor dies bonded to the redistribution layer, wherein the interconnect chip overlaps the semiconductor dies in a normal direction of the circuit substrate.

7. The package structure as claimed in claim 1, wherein the dummy bars are laterally spaced apart from the conductive connectors.

8. A package structure, comprising:
a circuit substrate;
a redistribution layer over the circuit substrate, wherein the redistribution layer comprises a first region and a second region outside the first region;
an interconnect chip disposed in the first region;
a plurality of dummy bars disposed in the first region and around the interconnect chip;
a plurality of conductive connectors in the second region; and
an underfill disposed between the circuit substrate and the redistribution layer and encapsulating the interconnect chip, the dummy bars and the conductive connectors.

9. The package structure as claimed in claim 8, further comprising a passivation layer over the circuit substrate, the dummy bars are formed on the passivation layer and misaligned with the interconnect chip in a normal direction of the circuit substrate.

10. The package structure as claimed in claim 9, wherein an opening is formed in the passivation layer and below the interconnect chip, and the dummy bars are laterally spaced apart from the opening.

11. The package structure as claimed in claim 8, wherein a distance between two adjacent dummy bars is less than a distance between two adjacent conductive connectors.

12. The package structure as claimed in claim 8, wherein the dummy bars are located on each side of the interconnect chip.

13. The package structure as claimed in claim 12, wherein the interconnect chip has a first side and a second side opposite to the first side, and an amount of the dummy bars on the first side is different from an amount of the dummy bars on the second side.

14. The package structure as claimed in claim 8, wherein the dummy bars comprise an insulation material.

15. A method for fabricating a package structure, comprising:
bonding a plurality of semiconductor dies over a first surface of a redistribution layer;
bonding an interconnect chip over a second surface of the redistribution layer, wherein the interconnect chip is located directly below the plurality of semiconductor dies;
forming a plurality of conductive connectors around the interconnect chip;
forming a plurality of dummy bars between the interconnect chip and the conductive connectors;
bonding the redistribution layer to a circuit substrate; and
filling an underfill between the redistribution layer and the circuit substrate.

16. The method as claimed in claim 15, wherein forming the dummy bars between the interconnect chip and the conductive connectors comprises:
forming a first plurality of dummy bars over the second surface of the redistribution layer.

17. The method as claimed in claim 16, wherein forming the dummy bars between the interconnect chip and the conductive connectors comprises:
forming a second plurality of dummy bars over the circuit substrate, wherein a width of the first plurality of dummy bars is different from a width of the second plurality of dummy bars.

18. The method as claimed in claim 17, wherein an edge of one of the first plurality of dummy bars is misaligned with an edge of one of the second plurality of dummy bars.

19. The method as claimed in claim 16, wherein the first plurality of dummy bars are spaced apart from the circuit substrate.

20. The method as claimed in claim 16, further comprising:
forming an opening in a passivation layer over the circuit substrate, wherein the opening is directly below the interconnect chip, and the dummy bars are laterally spaced apart from the opening.
